(19) United States
(12) Patent Application Publication
(10) Pub. No.: US 2012/0199917 A1
(43) Pub. Date: Aug. 9, 2012

(54) SEMICONDUCTOR DEVICE

(75) Inventor: Tetsu MOROOKA, Yokohama-shi (JP)

(73) Assignee: KABUSHIKI KAISHA TOSHIBA, Tokyo (JP)

(21) Appl. No.: 13/347,946

(22) Filed: Jan. 11, 2012

(30) Foreign Application Priority Data
Feb. 3, 2011 (JP) 2011-021748

(51) Int. Cl. H01L 27/088

(52) U.S. Cl. 257/401; 257/E27.06

(57) ABSTRACT

In one embodiment, a semiconductor device includes a substrate including a step which includes a first upper surface, a second upper surface having a height lower than a height of the first upper surface, and a step side surface located between the first and second upper surfaces. The device further includes a gate insulator provided continuously on the step side surface and the second upper surface of the substrate, and a gate electrode provided on the second upper surface of the substrate via the gate insulator to contact the gate insulator provided on the step side surface of the substrate. The device further includes a source region of a first conductivity type under the first upper surface, a drain region of a second conductivity type under the second upper surface, and a side diffusion region of the second conductivity type between the step side surface and the source region,

### CROSS REFERENCE TO RELATED APPLICATION

This application is based upon and claims the benefit of priority from the prior Japanese Patent Application No. 2011-21748, filed on Feb. 3, 2011, the entire contents of which are incorporated herein by reference.

### FIELD

Embodiments described herein relate to a semiconductor device.

### BACKGROUND

As an electronic device has been improved in size and portability, it has become important to reduce the power consumption of a semiconductor device which is used as a base component in the electronic device. A typical method of reducing the power consumption of the semiconductor device is to operate the semiconductor device at a low voltage. However, due to the advance in miniaturization of an MISFET, it has become difficult to suppress the short channel effect and to control variation in device characteristics. Therefore, it has become difficult to operate the semiconductor device at a low voltage.

For this reason, instead of the conventional MISFET, a field effect tunnel transistor has been studied. It uses band-to-band tunneling in a semiconductor layer, or tunneling through a junction between a metal layer and a semiconductor layer.

Examples of the tunnel transistor include a lateral device having a structure in which the band-to-band tunneling is generated in the lateral direction, and a longitudinal device having a structure in which the band-to-band tunneling is generated in the longitudinal direction. In the lateral device, the band-to-band tunneling is generated in a region where the source region and the channel region are in contact with each other. The lateral device is easily manufactured. However, the drain current in the lateral device is small because the region in which the band-to-band tunneling is generated in the lateral device is small as compared with the longitudinal device.

### BRIEF DESCRIPTION OF THE DRAWINGS

FIG. 1 is a side cross-sectional view showing a structure of a semiconductor device of a first embodiment;

FIGS. 2A to 4C are side cross-sectional views showing a method of manufacturing the semiconductor device of the first embodiment;

FIGS. 5A to 5C are side cross-sectional views showing cross sections of tunnel transistors configuring the semiconductor device of the first embodiment; and

FIG. 6 is a side cross-sectional view showing a structure of a semiconductor device of a second embodiment.

### DETAILED DESCRIPTION

Embodiments will now be explained with reference to the accompanying drawings.

An Embodiment described herein is a semiconductor device including a substrate including a step which includes a first upper surface, a second upper surface having a height lower than a height of the first upper surface, and a step side surface located between the first and second upper surfaces. The device further includes a gate insulator provided continuously on the step side surface and the second upper surface of the substrate, and a gate electrode provided on the second upper surface of the substrate via the gate insulator to contact the gate insulator provided on the step side surface of the substrate. The device further includes a source region of a first conductivity type, provided in the substrate under the first upper surface, a drain region of a second conductivity type, provided in the substrate under the second upper surface, and a side diffusion region of the second conductivity type, provided in the substrate between the step side surface and the source region.

### First Embodiment

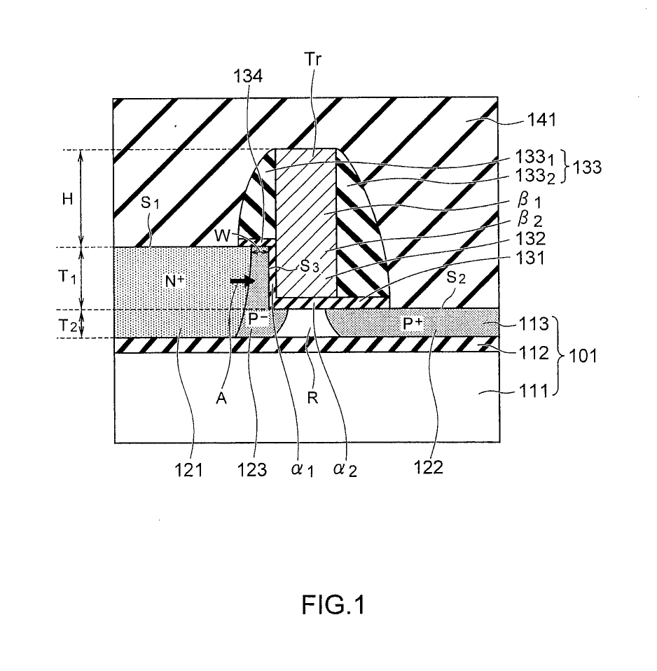

FIG. 1 is a side cross-sectional view showing a structure of a semiconductor device of a first embodiment.

FIG. 1 shows a tunnel transistor Tr configuring the semiconductor device. The semiconductor device of FIG. 1 includes a substrate 101, a source region 121, a drain region 122, a side diffusion region 123, a gate insulator 131, a gate electrode 132, sidewall insulators 133, and an underlying insulator 134 as components of the tunnel transistor Tr.

The substrate 101 is an SOI (Semiconductor on Insulator) substrate including a semiconductor substrate 111, an embedded insulating layer 112 on the semiconductor substrate 111, and a semiconductor layer 113 on the embedded insulating layer 112. In the present embodiment, the semiconductor substrate 111, the embedded insulating layer 112, and the semiconductor layer 113 are a silicon substrate, a silicon oxide layer, and a P-type silicon layer, respectively. The substrate 101 may be an ordinary semiconductor substrate instead of the SOI substrate.

The semiconductor layer 113 includes a step including a first upper surface S₁, a second upper surface S₂ having a height lower than a height of the first upper surface S₁, and a step side surface S₃ located between the first upper surface S₁ and the second upper surface S₂. In FIG. 1, the height difference between the first upper surface S₁ and the second upper surface S₂ is denoted by a character T₁, and the height difference between the second upper surface S₂ and the lower surface of the semiconductor layer 113 is denoted by a character T₂. In the present embodiment, T₁ is set to 100 nm or less for example, and T₂ is set to 20 nm or less for example.

Next, the source region 121, the drain region 122, and the side diffusion region 123 configuring the tunnel transistor Tr are described.

The source region 121 and the drain region 122 are formed in the semiconductor layer 113 under the first and second upper surfaces S₁ and S₂, respectively. Furthermore, the side diffusion region 123 is formed in the semiconductor layer 113 between the step side surface S₃ and the source region 121. In FIG. 1, the width of the side diffusion region 123 in the vicinity of the first upper surface S₁ (i.e., the distance between the step side surface S₃ and the source region 121) is denoted by a character W. In the present embodiment, W is set to 5 to 10 nm for example.

In the present embodiment, the source region 121 is an N⁺-type diffusion region, and the drain region 122 is a P⁺-type diffusion region. Furthermore, the side diffusion region 123 is a P⁻-type diffusion region. Therefore, the boundary surface between the source region 121 and the side diffusion region 123 is a PN junction surface. In FIG. 1, the region in the semiconductor layer 113 between the side diffusion region 123 and the drain region 122 is denoted by a character R. The region R is a P-type region because the semiconductor layer 113 is the P-type semiconductor layer. The N-type and the P-type are examples of first and second conductivity types, respectively.

In the present embodiment, the concentration of the N-type impurities in the source region 121, and the concentration of the P-type impurities in the drain region 122 are set to, for example, 1.0×10²⁰ to 1.0×10²¹ cm⁻³. Further, the concentration of the P-type impurities in the side diffusion region 123 is set to, for example, 1.0×10¹⁸ to 1.0×10¹⁹ cm⁻³, and the concentration of the P-type impurities in the R region is set to, for example, 1.0×10¹⁶ to 1.0×10¹⁸ cm⁻³. Both of the side diffusion region 123 and the region R correspond to the channel region of the tunnel transistor Tr. However, in the present embodiment, the P-type impurity concentration of the side diffusion region 123 is set higher than the P-type impurity concentration of the region R.

The source region 121, the drain region 122, the side diffusion region 123, and the semiconductor layer 113 may also be a P⁺-type region, an N⁺-type region, an N⁻-type region, and an N-type semiconductor layer, respectively.

Next, the gate insulator 131, the gate electrode 132, the sidewall insulator 133, and the underlying insulator 134 configuring the tunnel transistor Tr are described.

The gate insulator 131 is continuously formed on the step side surface S₃ and the second upper surface S₂ of the semiconductor layer 113. In FIG. 1, a portion of the gate insulator 131, formed on the step side surface S₃, is denoted by a character α₁, and a portion of the gate insulator 131, formed on the second upper surface S₂, is denoted by a character α₂. In the present embodiment, the thickness of the portion α₂ is set equal to or greater than the thickness of the portion α₁.

The gate electrode 132 is formed on the second upper surface S₂ via the gate insulator 131 (α₂) so as to contact the gate insulator 131 (a₁) formed on the step side surface S₃. As shown in FIG. 1, the gate electrode 132 includes a first portion β₁ protruding higher than the height of the first upper surface S₁, and a second portion β₂ located lower than the height of the first upper surface S₁. In FIG. 1, the height of the first portion β₁ (i.e., the height difference between the upper surface of the gate electrode 132 and the first upper surface S₁) is denoted by a character H. In the present embodiment, H is set to 50 nm or more for example, in order that a first sidewall insulator 133₁ described below can be formed on a side surface of the first portion β₁.

The sidewall insulators 133 are formed on side surfaces of the gate electrode 132. FIG. 1 shows a first sidewall insulator 133₁ formed on the side surface of the first portion β₁ on the first upper surface S₁ side, and a second sidewall insulator 133₂ formed on the side surfaces of the first and second portions β₁ and β₂ on the second upper surface S₂ side as the sidewall insulators 133. In the present embodiment, the first sidewall insulator 133₁ is formed on the first upper surface S₁ via the underlying insulator 134 which is an insulator different from the gate insulator 131. On the other hand, the second sidewall insulator 133₂ is formed on the second upper surface S₂ via the gate insulator 131.

In the present embodiment, the gate insulator 131, the gate electrode 132, the sidewall insulator 133, and the underlying insulator 134 are a silicon oxide layer, a polysilicon layer, a silicon nitride layer (or silicon oxide layer), and a silicon oxide layer, respectively. However, these insulators and electrode may also be formed with other insulators and electrode material, respectively.

Furthermore, FIG. 1 shows an inter layer dielectric 141 formed on the substrate 101 so as to cover the tunnel transistor Tr. The inter layer dielectric 141 is, for example, a silicon oxide layer.

(1) Structure and Operation of Tunnel Transistor Tr

In the following, the structure and operation of the tunnel transistor Tr will be described in detail with reference to FIG. 1.

In the present embodiment, the semiconductor layer 113 includes the step, and the gate insulator 131 and the gate electrode 132 are formed on the step side surface S₃. Furthermore, the P⁻-type side diffusion region 123 is formed between the step side surface S₃ and the N⁺-type source region 121.

As a result, in the present embodiment, the PN junction surface through which the band-to-band tunneling is generated is not formed under the gate electrode 132 but is formed in the side direction of the gate electrode 132. Therefore, the band-to-band tunneling of the tunnel transistor Tr is controlled in the side direction of the gate electrode 132.

In the present embodiment, when a predetermined gate voltage and a predetermined drain voltage are respectively applied to the gate electrode 132 and the drain region 122, the band-to-band tunneling is induced through the PN junction surface between the source region 121 and the side diffusion region 123 in the side direction of the step side surface S₃, as shown by the arrow A. Consequently, a drain current flows between the source region 121 and the drain region 122.

The present embodiment has an advantage that the region where the band-to-band tunneling is generated (i.e., the area of the PN junction surface in the side direction of the step side surface S₃) can be easily expanded by increasing the height T₁ of the step side surface S₃. This makes is possible to increase the drain current of the tunnel transistor Tr.

In the present embodiment, the PN junction surface is formed by forming the source region 121 and the side diffusion region 123. The side diffusion region 123 can be easily formed by a conventional ion implantation process. In the present embodiment, the side diffusion region 123 is formed in the substrate 101 in the side direction of the gate electrode 132. Therefore, the side diffusion region 123 can be more easily formed by oblique ion implantation, for example, as compared with a pocket region which is thinly formed in the upper surface of the substrate. Therefore, the present embodiment has an advantage that the PN junction surface through which the band-to-band tunneling is generated can be easily formed.

As described below, the gate electrode 132 of the present embodiment can be formed by applying a side wall forming process (more specifically, an etch-back process). Therefore, the present embodiment further has an advantage that the width of the gate electrode 132 can be easily miniaturized.

(2) Details of Structure of Semiconductor Device

Next, the structure of the semiconductor device shown in FIG. 1 will be described in more detail in consideration of the structure and operation of the tunnel transistor Tr described above.

First, the gate insulator 131 is described.

As described above, the thickness of the portion α₂ formed on the second upper surface S₂ is set equal to or greater than the thickness of the portion α₁ formed on the step side surface S₃. In the present embodiment, it is preferred that the thickness of the portion α₂ is set to be greater than the thickness of the portion α₁. This is because the electric field is concentrated more on the portion α₁ than on the portion α₂ so as to enable band-to-band tunneling to be easily induced.

The gate insulator 131 having such structure can be realized, for example, by forming the substrate 101 so that the second upper surface S₂ becomes a (110) plane and the step side surface S₃ becomes a (100) plane. In this case, when the gate insulator 131 is formed on the second upper surface S₂ and the step side surface S₃ of the semiconductor layer 113, the oxidation rate on the step side surface S₃ becomes higher than the oxidation rate on the second upper surface S₂. Therefore, the thickness of the portion α₂ becomes greater than the thickness of the portion α₁.

The gate insulator 131 having such structure can also be formed by anisotropic plasma oxidation (in the case of an oxide layer), and anisotropic plasma nitriding (in the case of a silicon oxynitride layer). Furthermore, the gate insulator 131 having such structure can also be formed by forming the portions α₁ and α₂ with different insulators. In this case, only the portion α₁ may be formed of high-k insulator, for example.

Next, the first sidewall insulator 133₁ is described.

As described above, the first portion β₁ of the gate electrode 132 is used to form the first sidewall insulator 133₁ on a side surface of the first portion β₁. The first sidewall insulator 133₁ is also used as a mask in forming the source region 121, as described below.

In the present embodiment, the first sidewall insulator 133₁ is formed on the first upper surface S₁ via the underlying insulator 134. This structure has an advantage that, for example, when the first sidewall insulator 133₁ is an insulator other than a silicon oxide layer, direct contact between the first sidewall insulator 133₁ and the substrate 101 in the vicinity of the PN junction surface can be avoided by forming the underlying insulator 134 by a silicon oxide layer.

On the other hand, as will be described below, the first sidewall insulator 133₁ may be formed directly on the first upper surface S₁. This is effective, for example, in such a case where the first sidewall insulator 133₁ is a silicon oxide layer, so that the first sidewall insulator 133₁ and the substrate 101 in the vicinity of the PN junction surface can be brought into direct contact with each other.

Next, the side diffusion region 123 is described. As described above, the tunnel transistor Tr of the present embodiment is configured such that the band-to-band tunneling is induced through the PN junction surface between the source region 121 and the side diffusion region 123 in the side direction of the step side surface S₃.

In the present embodiment, in order to facilitate the occurrence of the band-to-band tunneling, the P-type impurity concentration of the side diffusion region 123 is set higher than the P-type impurity concentration of the other channel region, that is, the P-type impurity concentration of the region R. Furthermore, the width W of the side diffusion region 123 in the vicinity of the first upper surface S₁ is set to a small width, 5 to 10 nm. The value of the width W may be set to a value other than the value of 5 to 10 nm as long as the width enables the necessary band-to-band tunneling to be induced.

It is preferred that the region R which is located substantially under the gate electrode 132 is entirely a depletion layer. This can be realized by making sufficiently small the height difference T₂ between the second upper surface S₂ and the lower surface of the semiconductor layer 113.

(3) Method of Manufacturing Semiconductor Device

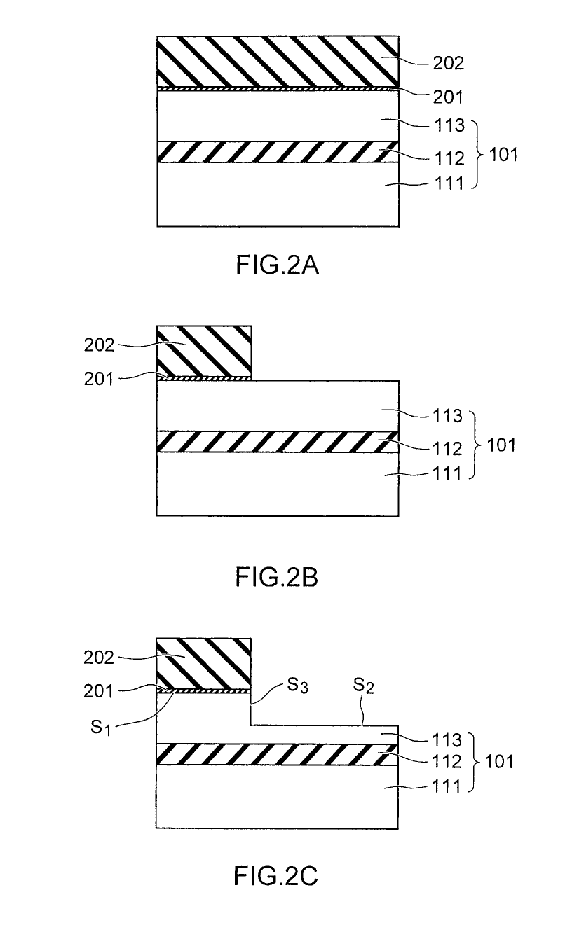

Next, a method of manufacturing the semiconductor device of the present embodiment will be described. FIGS. 2A to 4C are side cross-sectional views showing the method of manufacturing the semiconductor device of the present embodiment.

First, as shown in FIG. 2A, an underlying insulator material 201 for forming the underlying insulator 134, and a hard mask layer 202 are formed in this order on the substrate 101.

In the present embodiment, the substrate 101 is the SOI substrate including the semiconductor substrate 111, the embedded insulating layer 112, and the semiconductor layer 113. The underlying insulator material 201 is, for example, a silicon oxide layer formed by thermal oxidation, and the hard mask layer 202 is, for example, a silicon nitride layer. When the underlying insulator material 201 is an insulator other than a silicon oxide layer, or when the underlying insulator material 201 is not formed on the substrate 101, the hard mask layer 202 may be a silicon oxide layer.

Next, as shown in FIG. 2B, the hard mask layer 202 and the underlying insulator material 201 are etched by photolithography and RIE (Reactive Ion Etching).

Next, as shown in FIG. 2C, the semiconductor layer 113 is etched by using the hard mask layer 202 as a mask. As a result, a step is formed on the semiconductor layer 113. FIG. 2C shows the first upper surface S₁, the second upper surface S₂ and the step side surface S₃ which form the step. The timing to stop the etching of the semiconductor layer 113 is controlled, for example, by measuring the etching time.

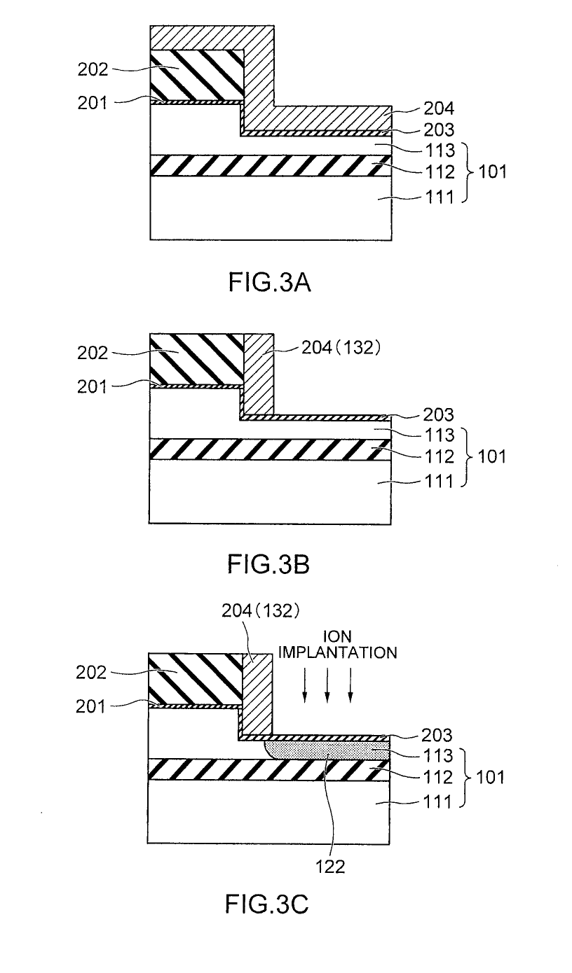

Next, as shown in FIG. 3A, a gate insulator material 203 for forming the gate insulator 131 is formed on the step side surface S₃ and the second upper surface S₂ of the semiconductor layer 113. The gate insulator material 203 is a silicon oxide layer formed by thermal oxidation, for example.

Next, as shown in FIG. 3A, a gate electrode material 204 for forming the gate electrode 132 is formed on the whole surface of the substrate 101. The gate electrode material 204 is, for example, a polysilicon layer. The thickness of the gate electrode material 204 formed in the process of FIG. 3A becomes the gate length of the tunnel transistor Tr.

Next, as shown in FIG. 3B, the gate electrode material 204 is etched back by dry etching so that the gate electrode material 204 in portions other than the side surfaces of the semiconductor layer 113, the underlying insulator material 201, and the hard mask layer 202 is removed. As a result, the gate electrode 132 in contact with the gate insulator material 203 on the step side surface S₃ is formed on the second upper surface S₂ via the gate insulator material 203.

Although the gate electrode 132 having a rectangular cross section is shown in FIG. 3B, it is considered in practice that the upper right corner of the gate electrode 132 in the figure is rounded off at the time of the etch back processing.

Next, as shown in FIG. 3C, a high-concentration P-type diffusion layer is formed by implanting P-type impurity ions into a region to be the drain region 122 by using the hard mask layer 202 and the gate electrode material 204 as a mask.

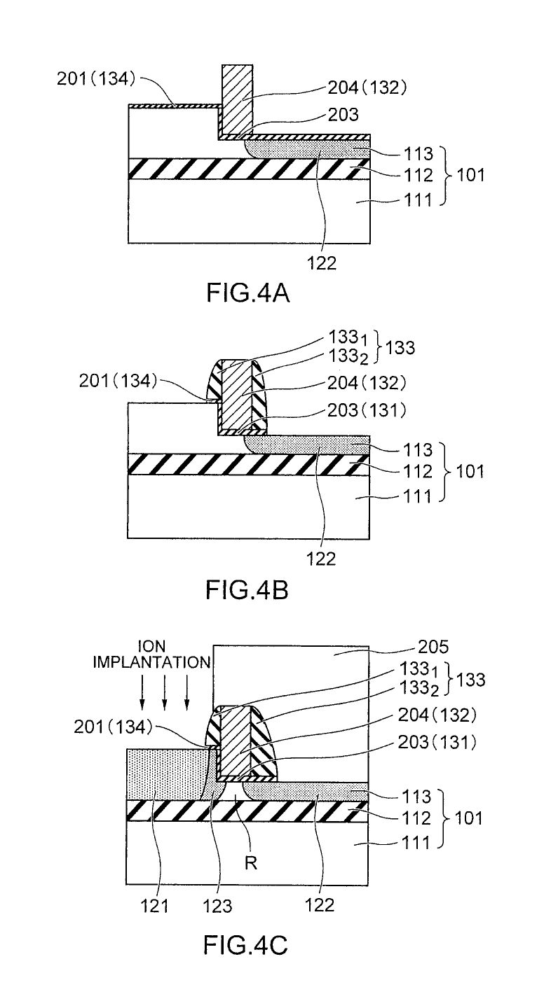

Next, as shown in FIG. 4A, the hard mask layer 202 is removed. As a result, the underlying insulator material 201 is exposed on the substrate 101.

Next, as shown in FIG. 4B, the sidewall insulators 133 are formed on both side surfaces of the gate electrode 132. The sidewall insulators 133 are formed, for example, by forming a silicon nitride layer on the whole surface of the substrate 101 and then etching back the silicon nitride layer. FIG. 4B shows the first sidewall insulator 133₁ formed on a side surface of the gate electrode 132 on the first upper surface S₁ side, and the second sidewall insulator 133₂ formed on a side surface of the gate electrode 132 on the second upper surface S₂ side.

Next, as shown in FIG. 4C, a resist film 205 covering the semiconductor layer 113 is formed by photolithography.

Next, as shown in FIG. 4C, a P-type diffusion layer is formed in the side and bottom directions of the gate electrode 132 by implanting P-type impurity ions into a region to be the side diffusion region 123 by oblique ion implantation using the resist film 205 and the first sidewall insulator 133₁ as a mask.

Next, as shown in FIG. 4C, a high-concentration N-type diffusion layer is formed by implanting N-type impurity ions into a region to be the source region 121 by ordinary ion implantation using the resist film 205 and the first sidewall insulator 133₁ as a mask.

In the present embodiment, inter layer dielectrics, contact plugs, via plugs, interconnect layers and the like are then formed on the substrate 101, so that the semiconductor device is completed.

The method of manufacturing the semiconductor device of the present embodiment has advantages that 1) the region in which the band-to-band tunneling is generated can be easily expanded, 2) the side diffusion region 123 can be easily formed, and 3) the width of the gate electrode 132 can be easily miniaturized, for example.

(4) Positional Relationship between Tunnel Transistors Tr

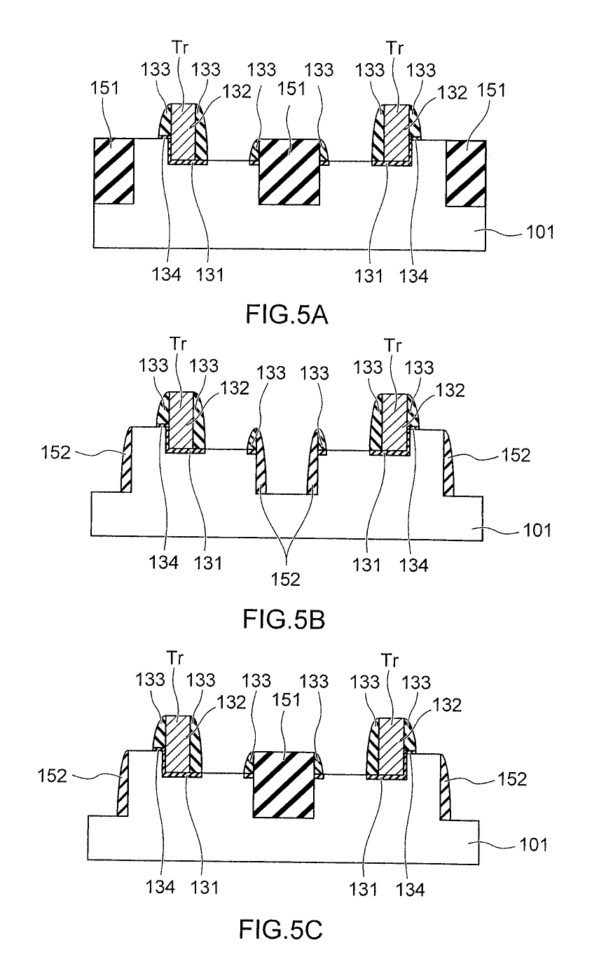

Next, a positional relationship between the tunnel transistors Tr on the substrate 101 will be described with reference to FIGS. 5A to 5C.

FIGS. 5A to 5C are side cross-sectional views showing cross sections of tunnel transistors Tr configuring the semiconductor device of the present embodiment.

FIG. 5A shows an example in which the tunnel transistors Tr are separated from each other by isolation insulators 151.

In FIG. 5A, steps are formed on the upper surface of the substrate 101 between the isolation insulators 151, and each of the tunnel transistors Tr is formed on a step side surface S₃ of each step.

The isolation insulators 151 in FIG. 5A are STI (Shallow Trench Isolation) insulators. The regions sandwiched between the Isolation insulators 151 are AA (Active Area) regions. In FIG. 5A, a step is formed in each AA region.

FIG. 5B shows an example in which the isolation insulators 151 are removed from the example shown in FIG. 5A. Such structure is referred to as a mesa type. In FIG. 5B, sidewall insulators 152 are formed on the sidewall surfaces of the isolation trenches.

FIG. 5C shows an example in which the example of FIG. 5A is combined with the example of FIG. 5B. FIG. 5C shows an isolation insulator 151 which separates two tunnel transistors Tr from each other, and also shows isolation trenches and sidewall insulators 152 which separate these tunnel transistors Tr from other tunnel transistors Tr adjacent to these tunnel transistors Tr in the gate length direction.

Note that any of the examples shown in FIG. 5A to FIG. 5C and other examples may be adopted as the semiconductor device of the present embodiment.

In FIGS. 5A to 5C, the steps are processed into a mirror symmetrical shape, but these steps may be processed into other shapes.

Noted that, in FIG. 5A to FIG. 5C, the illustration of the source region 121, the drain region 122, the side diffusion region 123, and the embedded insulator 112 is omitted for convenience of illustration.

(5) Effects of First Embodiment

Finally, effects of the first embodiment are described with reference to FIG. 1.

As described above, in the present embodiment, the step is formed on the upper surface of the substrate 101, and the gate insulator 131 and the gate electrode 132 are formed on the step side surface S₃. Furthermore, the side diffusion region 123 of the second conductivity type is formed between the step side surface S₃ and the source region 121 of the first conductivity type. Therefore, the present embodiment makes it possible to realize the tunnel transistor Tr which can induce the band-to-band tunneling through the PN junction surface between the source region 121 and the side diffusion region 123 in the side direction of the step side surface S₃.

Therefore, according to the present embodiment, the region in which the band-to-band tunneling is generated can be increased by increasing the height T₁ of the step side surface S₃. Furthermore, the PN junction surface through which the band-to-band tunneling is generated can be easily formed as compared with a so-called pocket region and the like. Furthermore, the width of the gate electrode 132 can be easily miniaturized by applying a sidewall formation process.

In the following, a second embodiment, which is a modification of the first embodiment, will be described focusing on differences from the first embodiment.

### Second Embodiment

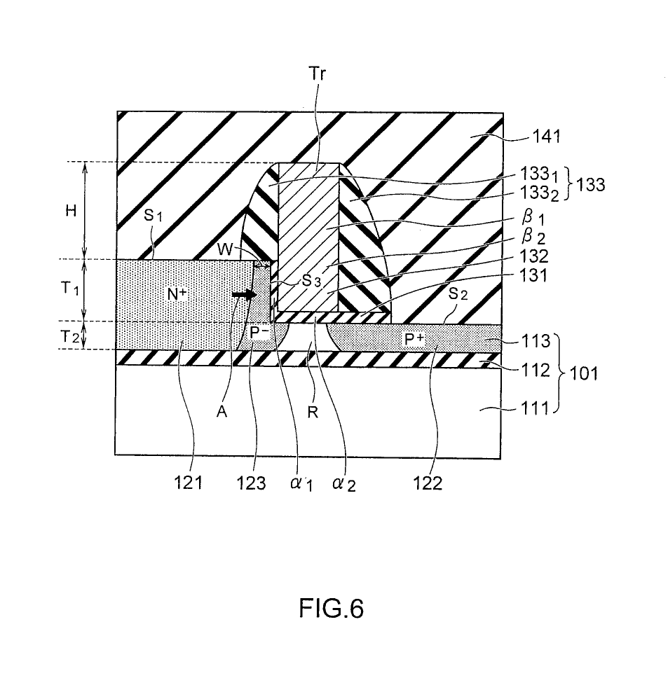

FIG. 6 is a side cross-sectional view showing a structure of a semiconductor device of a second embodiment.

In the first embodiment, the first sidewall insulator 133₁ is formed on the first upper surface S₁ via the underlying insulator 134 (FIG. 1). On the other hand, in the second embodiment, the first sidewall insulator 133₁ is formed directly on the first upper surface S₁ (FIG. 6).

The second embodiment is effective, for example, in such a case where the first sidewall insulator 133₁ is a silicon oxide layer and therefore the first sidewall insulator 133₁ can be brought into direct contact with the substrate 101 in the vicinity of the PN junction surface. The second embodiment has an advantage that the process of forming the underlying insulator 134 can be omitted.

The semiconductor device of the second embodiment can be manufactured by omitting the process of FIG. 2A which forms the underlying insulator material 201 in the method shown in FIGS. 2A to 4C.

Finally, effects of the second embodiment are described with reference to FIG. 6.

As described above, in the present embodiment, a step is formed on the upper surface of the substrate 101, and the gate insulator 131 and the gate electrode 132 are formed on the step side surface S₃. Furthermore, the side diffusion region 123 of the second conductivity type is formed between the step side surface S₃ and the source region 121 of the first conductivity type. Therefore, the present embodiment makes it possible to realize the tunnel transistor Tr which can induce the band-to-band tunneling through the PN junction surface between the source region 121 and the side diffusion region 123 in the side direction of the step side surface S₃, similarly to the first embodiment.

Therefore, according to the present embodiment, the region in which the band-to-band tunneling is generated can be increased by increasing the height T₁ of the step side surface S₃. Furthermore, the PN junction surface through which the band-to-band tunneling is generated can be easily formed as compared with a so-called pocket region and the like. Furthermore, the width of the gate electrode 132 can be easily miniaturized by applying a sidewall formation process.

While certain embodiments have been described, these embodiments have been presented by way of example only, and are not intended to limit the scope of the inventions. Indeed, the novel devices described herein may be embodied in a variety of other forms; furthermore, various omissions, substitutions and changes in the form of the devices described herein may be made without departing from the spirit of the inventions. The accompanying claims and their equivalents are intended to cover such forms or modifications as would fall within the scope and spirit of the inventions.

1. A semiconductor device comprising:
a substrate including a step which includes a first upper surface, a second upper surface having a height lower than a height of the first upper surface, and a step side surface located between the first and second upper surfaces;
a gate insulator provided continuously on the step side surface and the second upper surface of the substrate;
a gate electrode provided on the second upper surface of the substrate via the gate insulator to contact the gate insulator provided on the step side surface of the substrate;
a source region of a first conductivity type, provided in the substrate under the first upper surface;
a drain region of a second conductivity type, provided in the substrate under the second upper surface; and
a side diffusion region of the second conductivity type, provided in the substrate between the step side surface and the source region.

2. The device of claim 1, wherein the gate electrode comprises:
a first portion protruding higher than the height of the first upper surface, and
a second portion located lower than the height of the first upper surface.

3. The device of claim 2, further comprising:
a first sidewall insulator provided on a side surface of the first portion on a first upper surface side; and
a second sidewall insulator provided on side surfaces of the first and second portions on a second upper surface side.

4. The device of claim 3, wherein the first sidewall insulator is provided on the first upper surface via an underlying insulator.

5. The device of claim 3, wherein the first sidewall insulator is provided directly on the first upper surface.

6. The device of claim 2, wherein a height of the first portion is 50 nm or more.

7. The device of claim 1, wherein a difference between the heights of the first and second upper surfaces is 100 nm or less.

8. The device of claim 1, wherein the substrate comprises:
a semiconductor substrate;
an insulator on the semiconductor substrate; and
a semiconductor layer provided on the insulator and including the first and second upper surfaces.

9. The device of claim 8, wherein a difference between the height of the second upper surface and a height of a lower surface of the semiconductor layer is 20 nm or less.

10. The device of claim 1, wherein a width of the side diffusion region at the first upper surface is 5 to 10 nm.

11. The device of claim 1, wherein a thickness of the gate insulator on the second upper surface is equal to or greater than a thickness of the gate insulator on the step side surface.

12. The device of claim 1, wherein the gate insulator on the second upper surface and the gate insulator on the step side surface are insulators which are formed individually.

13. The device of claim 12, wherein the gate insulator on the step side surface is a high-k insulator.

14. The device of claim 1, wherein a concentration of second conductivity type impurities in the side diffusion region is higher than a concentration of second conductivity type impurities in the substrate under the gate electrode.

15. The device of claim 1, wherein a concentration of second conductivity type impurities in the side diffusion region is 1.0×10¹⁸ to 1.0×10¹⁹ cm⁻³.

16. The device of claim 1, wherein a concentration of second conductivity type impurities in the substrate under the gate electrode is 1.0×10¹⁶ to 1.0×10¹⁸ cm⁻³.

17. The device of claim 1, wherein a concentration of first conductivity type impurities in the source region and a concentration of second conductivity type impurities in the drain region are 1.0×10²⁰ to 1.0×10²¹ cm⁻³.

18. The device of claim 1, wherein the second upper surface and the step side surface are (110) and (100) planes, respectively.

19. The device of claim 2, wherein a corner portion of the first portion on a second upper surface side is rounded.

20. The device of claim 1, further comprising a tunnel
wherein the tunnel transistor is configured to induce band-to-band tunneling through a junction surface between the source region and the side diffusion region in a side direction of the step side surface.
